(19) United States
(12) Patent Application Publication
(10) Pub. No.: US 2011/0261613 A1
(43) Pub. Date: Oct. 27, 2011

(54) PHASE CHANGE MEMORY ARRAY BLOCKS WITH ALTERNATE SELECTION

(75) Inventor: Hong Beom PYEON, Ottawa (CA)

(73) Assignee: MOSAID TECHNOLOGIES INCORPORATED, Ottawa (CA)

(21) Appl. No.: 13/044,701

(22) Filed: Mar. 10, 2011

Related U.S. Application Data
(60) Provisional application No. 61/328,421, filed on Apr. 27, 2010.

(51) Int. Cl. G11C 11/00

(52) U.S. Cl. 365/163; 365/148

(57) ABSTRACT

A phase change memory is disclosed. The phase change memory has a plurality of block units. The block units are alternately selected. The alternate block unit selection suppresses peak current ground bouncing on sub-wordline and connected ground line through sub-wordline driver transistor. An alternate bitline selection avoids adjacent cell heating interference in the selected block unit.

### RELATED APPLICATION

This application claims the benefit of U.S. Provisional Patent Application No. 61/328,421 filed Apr. 27, 2010, which is hereby incorporated by reference in its entirety.

### FIELD

The present invention relates generally to a semiconductor memory. More particularly, the present invention relates to a phase change memory.

### BACKGROUND

At least one type of phase change memory device—PRAM (phase-change random access memory)—uses the amorphous state to represent a logical ‘1’ and the crystalline state to represent a logical ‘0’. In a PRAM device, the crystalline state is referred to as a “set state” and the amorphous state is referred to as a “reset state”. Accordingly, a memory cell in a PRAM stores a logical ‘0’ by setting a phase change material in the memory cell to the crystalline state, and the memory cell stores a logical ‘1’ by setting the phase change material to the amorphous state.

The phase change material in a PRAM is converted to the amorphous state by heating the material to a first temperature above a predetermined melting temperature and then quickly cooling the material. The phase change material is converted to the crystalline state by heating the material at a second temperature lower than the melting temperature but above a crystallizing temperature for a sustained period of time. Accordingly, data is programmed to memory cells in a PRAM by converting the phase change material in memory cells of the PRAM between the amorphous and crystalline states using heating and cooling as described above.

The phase change material in a PRAM typically comprises a compound including germanium (Ge), antimony (Sb), and tellurium (Te), i.e., a “GST” compound. The GST compound is well suited for a PRAM because it can quickly transition between the amorphous and crystalline states by heating and cooling. In addition to, or as an alternative for the GST compound, a variety of other compounds can be used in the phase change material. Examples of the other compounds include, but are not limited to, 2-element compounds such as GaSb, InSb, InSe, Sb2Te3, and GeTe, 3-element compounds such as GeSbTe, GaSeTe, InSbTe, SnSb2Te4, and InSbGe, or 4-element compounds such as AgInSbTe, (GeSn)SbTe, GeSb(SeTe), and Te81Ge15Sb2S2.

The memory cells in a PRAM are called “phase change memory cells”. A phase change memory cell typically comprises a top electrode, a phase change material layer, a bottom electrode contact, a bottom electrode, and an access transistor. A read operation is performed on the phase change memory cell by measuring the resistance of the phase change material layer, and a program operation is performed on the phase change memory cell by heating and cooling the phase change material layer as described above.

A phase change memory device typically includes a memory cell array, a write driver circuit, and a column selection circuit. The memory cell array has a plurality of block units and a plurality of wordline drivers. Each of the plurality of block units is connected between a pair of adjacent wordline drivers among the plurality of wordline drivers and comprises a plurality of memory blocks. The write driver circuit comprises a plurality of write driver units. Each of the write driver units includes a plurality of write drivers adapted to provide respective programming currents to a corresponding block unit among the plurality of block units. The column selection circuit is connected between the memory cell array and the write driver circuit and is adapted to select at least one of the plurality of memory blocks in response to a column selection signal to provide corresponding programming currents to at least one of the plurality of memory blocks.

FIG. 1A depicts an example phase change memory cell that employs a MOS transistor. Referring to FIG. 1A, a memory cell 10 includes a phase change resistance element 11 (also labeled “GST”) comprising the GST compound and a negative metal-oxide semiconductor (NMOS) transistor 12 (also labeled “NT”). The phase change resistance element 11 is connected between a bitline B/L and the NMOS transistor 12. The NMOS transistor 12 is connected between the phase change resistance element 11 and ground. In addition, the NMOS transistor 12 has a gate connected to a wordline W/L.

The NMOS transistor 12 is turned on in response to a wordline voltage applied to the wordline W/L. When the NMOS transistor 12 is turned on, the phase change resistance element 11 receives a current through bitline B/L. In the particular example shown in FIG. 1A, the phase change resistance element 11 is connected between bitline B/L and the NMOS transistor 12, the phase change resistance element 11 could alternatively be connected between the NMOS transistor 12 and ground.

FIG. 1B depicts an example diode type phase change memory cell. Referring to FIG. 1B, a memory cell 20 comprises a phase change resistance element 21 (also labeled “GST”) connected to a bitline B/L, and a diode 22 (also labeled “D”) connected between the phase change resistance element 21 and a wordline W/L. The phase change memory cell 20 is accessed by selecting wordline W/L and bitline B/L. In order for the phase change memory cell 20 to work properly, wordline W/L must have a lower voltage level than bitline B/L when wordline W/L is selected (this a is forward bias condition) so that current can flow through the phase change resistance element 21. If wordline W/L has a higher voltage than bitline B/L, the diode 22 is reverse-biased and no current flows through the phase change resistance element 21. To ensure that wordline W/L has a lower voltage level than bitline B/L, wordline W/L is generally connected to ground when selected.

In FIGS. 1A and 1B, the phase change resistance elements 11 and 21 can alternatively be broadly referred to as “memory elements” and NMOS transistor 12 and diode 22 can alternatively be broadly referred to as “select elements”.

The operation of the phase change memory cells 10 and 20 is described below with reference to FIG. 2. In particular, FIG. 2 is a graph illustrating temperature characteristics of the phase change resistance elements 11 and 21 during programming operations of the memory cells 10 and 20. In FIG. 2, a reference numeral “1” denotes temperature characteristics of the phase change resistance elements 11 and 21 during a transition to the amorphous state, and a reference numeral “2” denotes temperature characteristics of the phase change resistance elements 11 and 21 during a transition to the crystalline state.

In a transition to the amorphous state, a current is applied to the GST compound in the phase change resistance elements 11 and 21 for a duration T1 to increase the temperature of the GST compound above a melting temperature Tm. After duration T1, the temperature of the GST compound is rapidly decreased, or “quenched”, and the GST compound assumes the amorphous state. On the other hand, in a transition to the crystalline state, a current is applied to the GST compound in the phase change resistance elements 11 and 21 for an interval T2 (T2>T1) to increase the temperature of the GST compound above a crystallization temperature Tx. After time duration T2, the GST compound is slowly cooled down below the crystallization temperature so that it assumes the crystalline state. In the illustrated example, t1 is the middle point of temperature change from high to low. T1 might, for example, be about 50 ns, and T2 about 200 ns, but these may vary depending upon PCM cell implementation.

A phase change memory device typically comprises a plurality of phase change memory cells arranged in a memory cell array. Within the memory cell array, each of the memory cells is typically connected to a corresponding bitline and a corresponding wordline. For example, the memory cell array may comprise bitlines arranged in columns and wordlines arranged in rows, with a phase change memory cell located near each intersection between a column and a row.

Typically, a row of phase change memory cells connected to a particular wordline is selected by applying an appropriate voltage level to the particular wordline. For example, to select a row of phase change memory cells similar to phase change memory cell 10 as shown in FIG. 1A, a relatively high voltage level is applied to a corresponding wordline W/L to turn on the NMOS transistor 12. Alternatively, to select a row of phase change memory cells similar to the phase change memory cell 20 as shown in FIG. 1B, a relatively low voltage level is applied to a corresponding wordline W/L so that current can flow through the diode 22.

FIG. 3 illustrates one cell array selection for all IO operations. As shown in FIG. 3, in the case where a programming current is simultaneously applied to the plurality of memory cells connected with one wordline, a voltage level of the wordline may undesirably increase due to parasitic resistance in the wordline. As the voltage level of the wordline increases, programming characteristics of the plurality of memory cells may deteriorate. For example, in the diode type phase change memory cell with diode of FIG. 1B, if the voltage level of wordline W/L increases undesirably, diode 22 may not completely turn on.

FIG. 4 is a block diagram illustrating a design that attempts to address the wordline voltage level increase issue. FIG. 4 shows a memory cell array 110, column selection circuit 130, and write driver circuit 140. Each of first through fourth block units 111 through 114 comprises four memory blocks (not shown). Each memory block comprises a plurality of phase change memory cells. A main wordline (MWL) connects to the block units 111 to 114 through subwordline drivers (SWD) WD1, WD2, WD3, WD4, WD5. The use of SWDs may prevent wordline voltage from increasing undesirably.

### SUMMARY

Embodiments are provided that include the three features of a) partitioned IO, b) alternating sub-block selection, and c) alternating bit-lines. More generally, in some embodiments, a PCM (phase change memory) configuration is provided that includes one of the following:

i) partitioned IO;

ii) alternating sub-block selection;

iii) alternating bit-lines;

iv) partitioned IO and alternating sub-block selection;

v) partitioned IO and alternating bit-lines;

vi) alternating sub-block selection and alternating bit-lines;

vii) partitioned IO and alternating sub-block selection and alternating bit-lines.

A broad aspect of the invention provides an apparatus comprising a plurality of adjacent phase change memory (PCM) cells, in which memory location for accessing includes a subset of the PCM cells, such that each PCM cell of the subset is non-adjacent to each other PCM cell of the subset.

In some embodiments, the plurality of adjacent PCM cells is divided into a first set of odd numbered PCM cells and a second set of even numbered PCM cells, such that the cells of the first and second set alternate between belonging to the first set and belonging to the second set; and the apparatus further comprises a selector for selecting the first set of cells or the second set of cells.

In some embodiments, when the selector selects the first set of cells, a memory location for reading or writing comprises the first set of cells and not the second set of cells; when the selector selects the second set of cells, a memory location for reading or writing comprises the second set of cells and not the first set of cells.

In some embodiments, the selector comprises:

a first output connected to the first set of cells;

a second output connected to the second set of cells.

In some embodiments, the plurality of adjacent PCM cells further comprise a third set of odd numbered PCM cells and a fourth set of even numbered set of PCM cells, such that the cells of the third and fourth sets alternate between belonging to the third set and belonging to the fourth set; and the selector comprises:

a first output connected to the first set of cells;

a second output connected to the second set of cells;

a third output connected to the third set of cells; and

a fourth output connected to the fourth set of cells.

In some embodiments, the apparatus further comprises a first set of bit lines and a second set of bitlines, each bitline comprising a switching element for selecting the bitline;

wherein the switching elements of the first set of bitlines are connected to the first output and the switching element of the second set of bitlines are connected to the second output.

Another broad aspect of the invention provides an apparatus comprising:

a first memory cell array comprising a first plurality of PCM block units, each PCM block unit containing a plurality of memory cells, the first plurality of PCM block units divided into a first block set and a second block set such that each PCM block unit belonging to the first block set is non-adjacent to any other PCM block unit of the first block set, and each PCM block unit belonging to the second block set is non-adjacent to any other PCM block unit of the second block set;

a first selector configured to select between the first block set and the second block set; and

a wordline driver structure comprising:

a first plurality of sub-wordline drivers; and

a first main wordline driver that drives the first plurality of PCM block units via the first plurality of sub-wordline drivers,

wherein when the first selector selects the first block set, a memory location for accessing comprises memory cells of each block of the first block set, and when the first selector selects the second block set, a memory location for accessing comprises memory cells of each block of the second memory set.

In some embodiments, each PCM block unit comprises:

a plurality of adjacent PCM (phase change memory) cells;

wherein for a PCM block unit selected by the first selector, the memory location for accessing includes a subset of the PCM cells of the PCM block unit, such that each PCM cell of the subset is non-adjacent to each other PCM cell of the subset.

In some embodiments, each PCM block unit comprises a plurality of adjacent memory cells divided into a first set of odd numbered memory cells and a second set of even numbered set of memory cells, such that the cells of the first and second set alternate between belonging to the first set and belonging to the second set; and the apparatus further comprising a second selector that selects between the first sets of cells and the second sets of cells.

In some embodiments:

when the first selector selects the first block set and the second selector selects the first set of cells, a memory location for reading or writing comprises memory cells of the first set of cells of each block of the first block set;

when the first selector selects the first block set and the second selector selects the second set of cells, a memory location for reading or writing comprises memory cells of the second set of cells of each block of the first block set;

when the first selector selects the second block set and the second selector selects the first set of cells, a memory location for reading or writing comprises memory cells of the first set of cells of each block of the second block set;

when the first selector selects the second block set and the second selector selects the second set of cells, a memory location for reading or writing comprises memory cells of the second set of cells of each block of the second block set.

In some embodiments, for each PCM block, the plurality of adjacent PCM cells further comprise a third set of odd numbered PCM cells and a fourth set of even numbered set of PCM cells, such that the cells of the third and fourth sets alternate between belonging to the third set and belonging to the fourth set;

wherein the second selector comprises:

a first output connected to the first set of cells;

a second output connected to the second set of cells;

a third output connected to the third set of cells; and

a fourth output connected to the fourth set of cells.

In some embodiments, the apparatus further comprises:

a second memory cell array comprising a second plurality of PCM block units, the second plurality of PCM block units divided into a third block set and a fourth block set such that each PCM block unit belonging to the third set is non-adjacent to any other PCM block unit of the third set, and each PCM block unit belonging to the fourth set is non-adjacent to any other PCM block unit of the fourth set;

the wordline driver structure further comprises a second main wordline driver that drives the second plurality of PCM block units via a second plurality of sub-wordline drivers;

the first selector selects one of:

a) both the first block set and the third block set;
b) both the second block set and the fourth block set;

wherein when the selector selects the first block set and the third block set, a memory location for accessing comprises memory cells of each block of the first block set and memory cells of each block of the third block set;

wherein when the selector selects the second block set and the fourth block set, the memory location for accessing comprises memory cells of each block of the second block set and memory cells of each block of the fourth block set.

In some embodiments, the apparatus further comprises:

an address decoder;

wherein the first main wordline driver and the second main wordline driver are commonly activated by the address decoder.

In some embodiments, each PCM block unit comprises a plurality of adjacent PCM (phase change memory) cells;

wherein for a PCM block unit selected by the first selector, the memory location for accessing includes a subset of the PCM cells of the PCM block unit, such that each PCM cell of the subset is non-adjacent to each other PCM cell of the subset.

In some embodiments, each PCM block unit comprises a plurality of adjacent memory cells divided into a first set of odd numbered memory cells and a second set of even numbered set of memory cells, such that the cells of the first and second set alternate between belonging to the first set and belonging to the second set; and the apparatus has a second selector that selects between the first sets of cells and the second sets of cells.

In some embodiments,

when the first selector selects the first block set and the second selector selects the first set of cells, a memory location for reading or writing comprises memory cells of the first set of cells of each block of the first block set;

when the first selector selects the first block set and the second selector selects the second set of cells, a memory location for reading or writing comprises memory cells of the second set of cells of each block of the first block set;

when the first selector selects the second block set and the second selector selects the first set of cells, a memory location for reading or writing comprises memory cells of the first set of cells of each block of the second block set;

when the first selector selects the second block set and the second selector selects the second set of cells, a memory location for reading or writing comprises memory cells of the second set of cells of each block of the second block set.

In some embodiments, for each PCM block, the plurality of adjacent PCM cells further comprise a third set of odd numbered PCM cells and a fourth set of even numbered PCM cells, such that the cells of the third and fourth sets alternate between belonging to the third set and belonging to the fourth set;

wherein the selector comprises a first output connected to select the first set of cells, a second output connected to select the second set of cells, a third output connected to select the third set of cells, and a fourth output connected to select the fourth set of cells.

Another broad aspect of the invention provides a memory device comprising:

a memory cell array comprising a first PCM array and a second PCM array, the first PCM array comprising a first plurality of PCM block units, the second PCM array comprising a second plurality of PCM block units;

a wordline driver structure comprising, for each of a plurality of wordlines:

a first main wordline driver configured to drive the first PCM array via a first plurality of sub-word drivers configured to drive the first plurality of PCM block units;

a second main wordline driver configured to drive the second PCM array via a second plurality of sub-word drivers configured to drive the second plurality of PCM block units;

an address decoder configured to commonly activate the first main wordline driver and the second main wordline driver;

wherein a memory location for accessing comprises selected memory cells of the first memory cell array and selected memory cells of the second memory cell array.

In some embodiments, the memory location for reading or writing comprises selected memory cells of the first memory cell array and selected memory cells of the second memory cell array.

Another broad aspect provides a method comprising:

accessing phase change memory cells such that a memory location for accessing includes a subset of the PCM cells, such that each PCM cell of the subset is non-adjacent to each other PCM cell of the subset.

Another broad aspect provides a method comprising:

for a first memory cell array comprising a first plurality of PCM block units, each PCM block unit containing a plurality of memory cells, the first plurality of PCM block units divided into a first block set and a second block set such that each PCM block unit belonging to the first block set is non-adjacent to any other PCM block unit of the first block set, and each PCM block unit belonging to the second block set is non-adjacent to any other PCM block unit of the second block set, selecting between the first block set and the second block set;

using a first main wordline driver to drive the first plurality of PCM block units via a first plurality of sub-wordline drivers,

wherein when the first block set is selected, accessing a memory location that comprises memory cells of each block of the first block set, and when the second block set is selected, accessing a memory location for accessing that comprises memory cells of each block of the second memory set.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1A is a circuit diagram illustrating a phase change memory cell with a MOS cell;

FIG. 1B is a circuit diagram illustrating a diode type phase change memory cell;

FIG. 2 is a graph of current pulses during the set and reset operations;

FIG. 3 is a circuit diagram showing one cell array selection for all IO operations;

FIG. 4 is a block diagram illustrating one solution to the Vss ground level up;

FIG. 5 is a block diagram of a phase change memory array configuration with partitioned I/O assignment and alternate block unit selection;

FIG. 6 is a block diagram with partial circuit details of a phase change memory array configuration;

FIG. 7 is a block diagram showing alternate PCM block unit selection as a function of an address;

FIGS. 8A to 8C are detailed circuit diagrams of a phase change memory configuration with non-adjacent cells;

FIG. 9 is circuit diagram of a write driver with address control according to one embodiment of the present invention;

FIG. 10 is a timing diagram showing write operation timing.

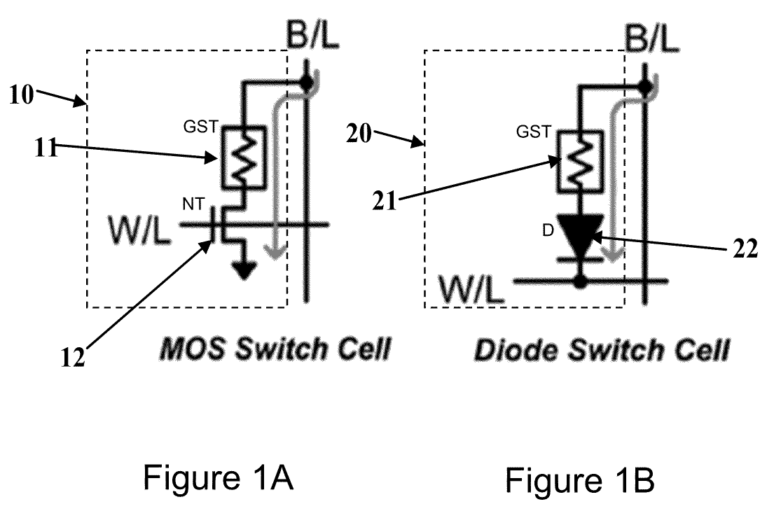

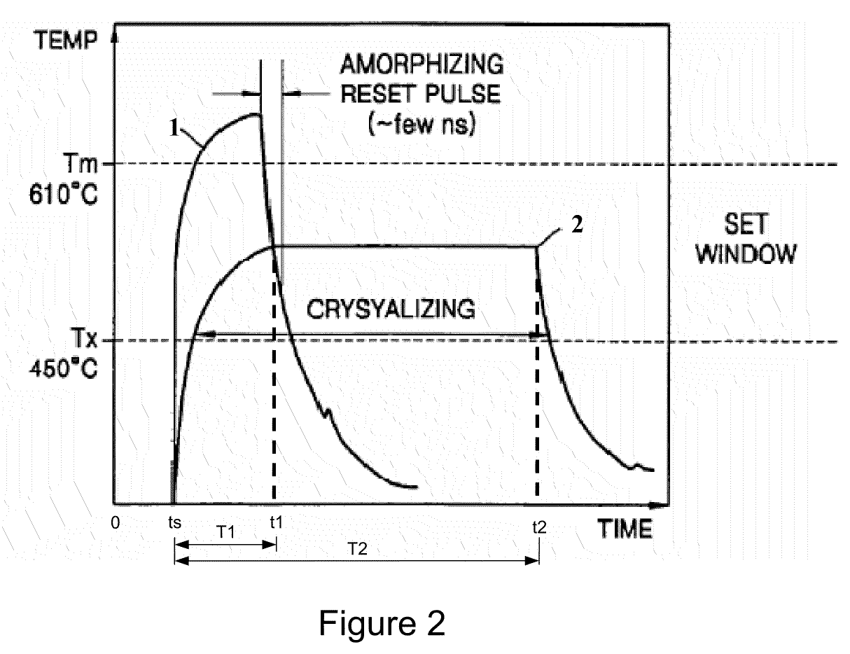

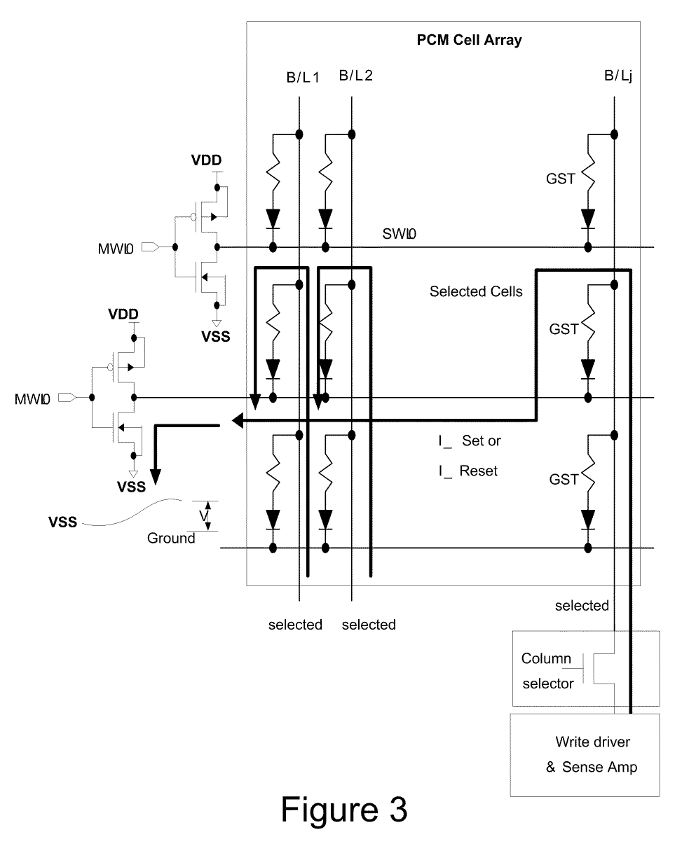

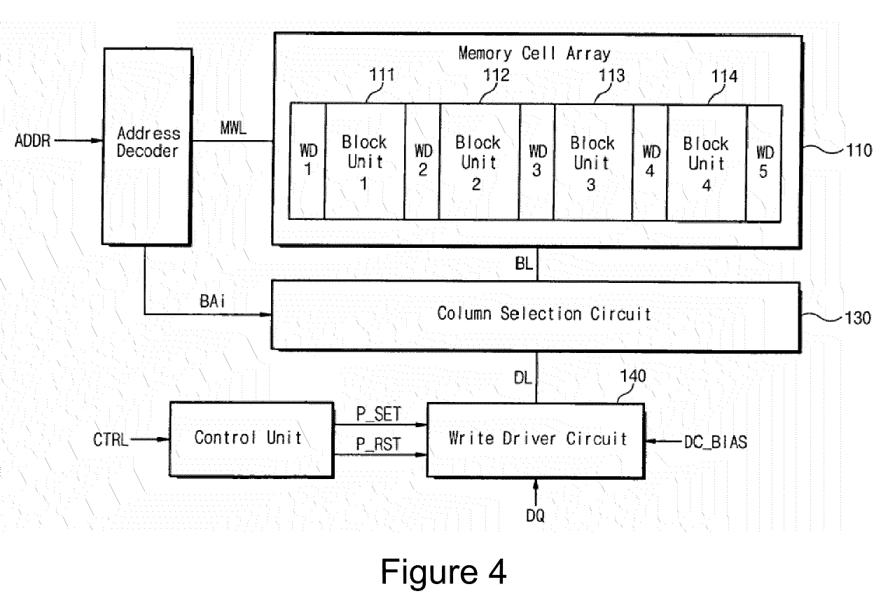

### DETAILED DESCRIPTION

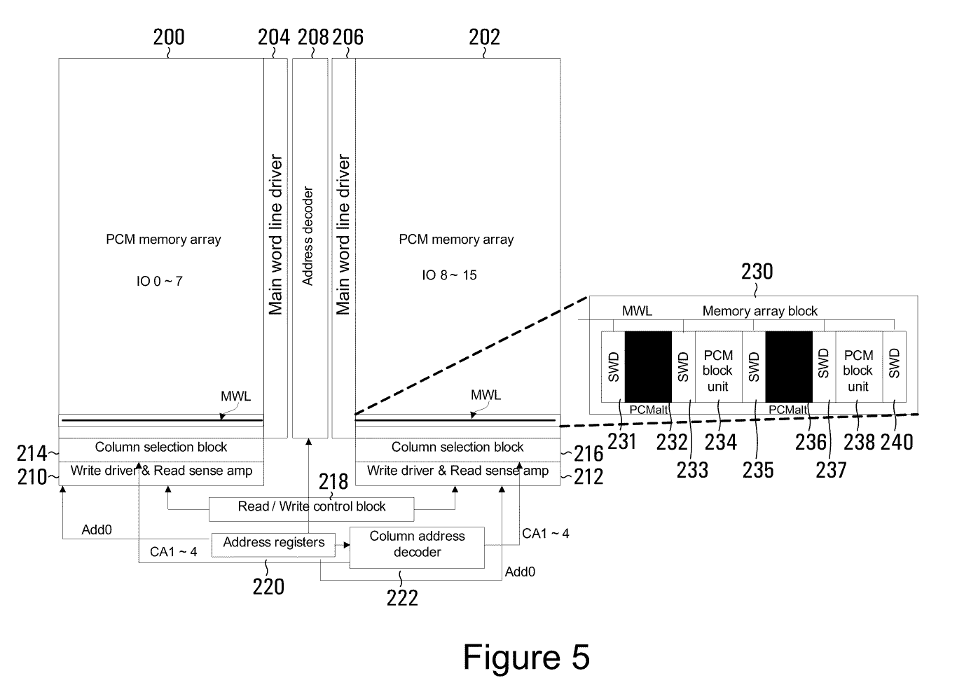

FIG. 5 is a block diagram of a phase change memory cell array having partitioned I/O assignment with alternate sub-block unit selection that can reduce the peak current concentration on the same local ground line and selected sub-wordline which goes to low through the sub-wordline driver consisting of PMOS and NMOS (inverter).

FIG. 5 shows a first PCM memory array 200 and a second PCM array 202 to be accessed. The I/O assignment is partitioned in the sense that the first PCM memory array 200 is associated with IO0˜7 and the second PCM memory array 202 associated with IO8˜15. PCM memory array 200 has associated write driver and read sense amplifier 210, and column selection block 214. Similarly, PCM memory array 202 has associated write driver and read sense amplifier 212 and column selection block 216. An address decoder 208 is connected to a main word driver 204 for the PCM memory array 200 and is connected to a main word driver 206 for PCM memory array 202. A read/write control block 218 controls whether a read or write is being performed. Address registers 220 contain the addresses to which read or write are to be performed. A column address decoder 222 receives an output of the address registers and generates outputs CA1˜4 which are passed to column selection blocks 214 and 216. In addition, an output Add0 of the address register 220 is connected to the write driver and read sense amplifiers 210,212.

Elements 210,212,220 collectively select between a first block set and a second block set. More generally, some embodiments have a selector configured to select between a first block set and a second block set. Elements 210,212,220 constitute a specific example of such a selector; however, other implementations are possible.

An expanded view of one of half of a main wordline of PCM memory array 202 is indicated generally at 230. The other half of the main wordline is in PCM array 200. Other word lines are similar. Shown are four PCM block units 232,234,236,238 situated between parts of sub-wordline drivers 231,233,235,237,240.

It can be seen immediately that the main wordlines are split in two. Half of a given main wordline is in PCM memory array 200 and the other half of the main word line is in PCM memory array 202. For a given address, alternate PCM block units are selected. In the illustrated example, PCM block units 232 and 236 are shaded indicating selection. Two units in PCM memory array 200 would also be selected (not shown) such that a total of four

PCM block units are selected. Assuming each PCM block unit can be used to store four bits, a 16 bit word can be written to the selected PCM block units.

In order to select alternate PCM (Phase Change Memory) block units, an input address, Add0, is used as a selection signal as shown in FIG. 5. Add0 may, for example, be the LSB or MSB of address bits; the particular selection depends on the address assignment of the PCM design. In the illustrated example, if Add0 is equal to zero, the first and third PCM block units are selected. Otherwise, the second and forth are selected (Add0=1 case).

By employing such partitioned IO configuration and alternate sub-block unit selection, when simultaneous programming is performed, the ground bouncing which might otherwise invoke an undesirable increase of sub-wordline voltage can be suppressed effectively without chip area penalty. As well, with the center placement of address decoder, the parasitic resistance effect of main wordline and sub-wordline are also reduced.

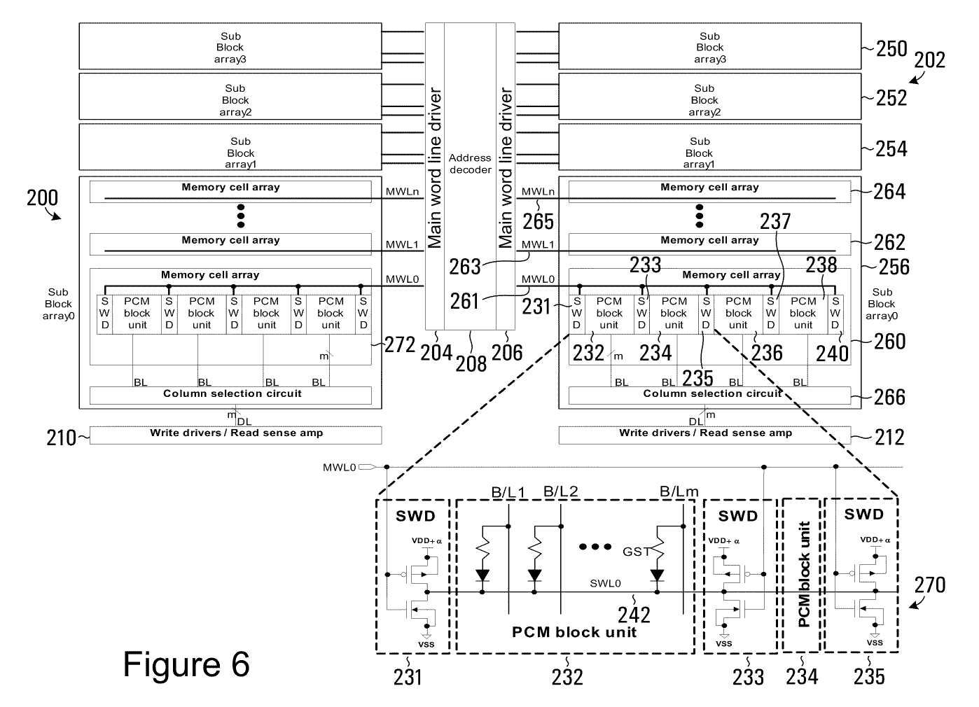

FIG. 6 shows an example implementation of the circuit of FIG. 5. Like reference numbers are used to identify like elements where appropriate. In the example of FIG. 6, PCM memory array 202 is composed of four subblock arrays 250,252,254,256. The details of subblock array 256 are shown in FIG. 6, but the other subblock arrays 250,252,254 are similar. The subblock array 256 is composed of n memory cell arrays each driven by a respective main wordline and only three of which 260,262,264 are shown in this example. Memory cell array 260 is driven by main wordline MWL0 261; memory cell array 262 is driven by main wordline MWL1 263, and memory cell array 264 is driven by main wordline MWLn 265. The details of memory cell array 260 are shown by way of example but the other memory cell arrays 262,264 are similar. The structure of the memory cell array 260 is similar to that described with reference to FIG. 5, reference number 230 and features five sub-wordline drivers 231,233,235,237,240 and four PCM block units 232,234,236,238. Each PCM block unit, such as PCM block unit 232, contains m phase change memory cells. The main wordline for the memory cell array, in this case, MWL0, is commonly connected to each of the sub-word drivers 231,233, 235,237,240. Column selection circuit 266 outputs m bitlines (BL) to each PCM block unit. Also shown are write drivers/read sense amplifier 212 having m DL (data line) outputs, to the column selection circuit 266.

Similar functionality is shown for PCM memory array 200. Selected cells of memory cell array 260 of PCM memory array 202 and memory cell array 272 of PCM memory array 200 together form one 16 bit storage location.

Generally indicated at 270 is an expanded circuit view of subblock array 260. It can be seen that the main wordline MWL0 is connected to each sub-wordline driver 231, 233, 235, 237, 240. The sub-wordline drivers drive a subwordline SWL0 242 that is shared within the same sub block array as shown in FIG. 6. In some embodiments, the sub-wordlines are implemented with metal layer material rather than active layer material (n+); this kind of connection helps to reduce the sub-wordline parasitic resistance effect.

In the illustrated embodiment, to reduce the operation delay due to long main wordline length, the address decoder is placed into the center of the chip. However, it should be understood that in some embodiments, a structure similar to that of FIG. 6 that features alternate PCM block unit selection may be implemented but with only a single set of sub block arrays on one side of an address decoder, in which case there is no I/O partitioning.

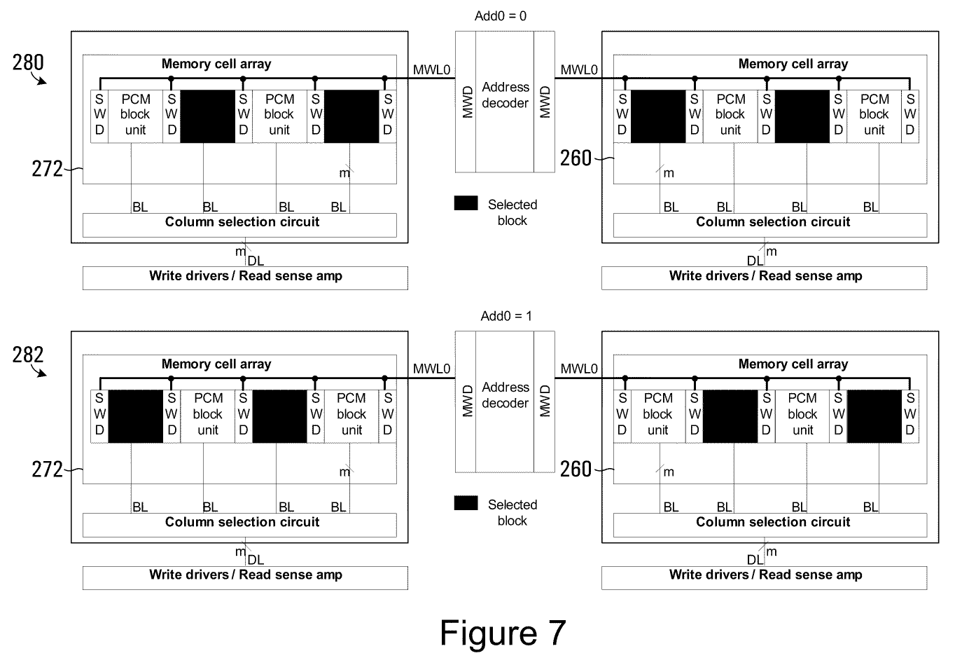

FIG. 7 shows a specific example of PCM block unit selection as a function of the value of Add0. The top part of FIG. 7, generally indicated at 280, shows PCM block unit selection within memory cell array 260 and memory cell array 270 for the case where Add0=0. The bottom part of the figure, generally indicated at 282 shows PCM block unit selection for the same memory cell arrays for the case where Add0=1.

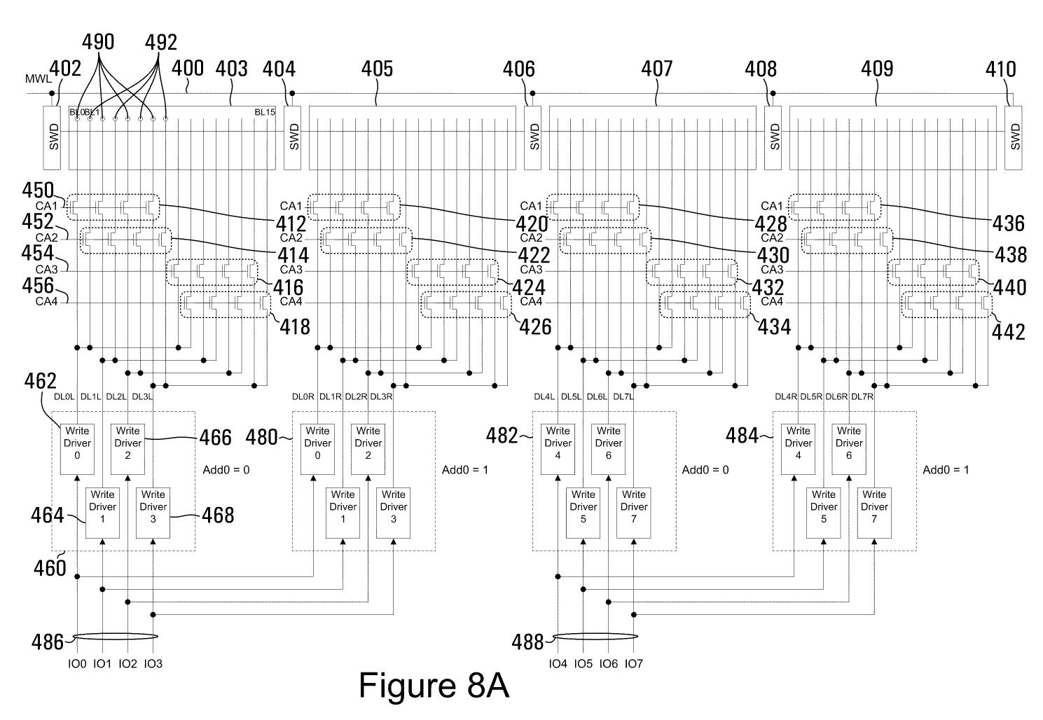

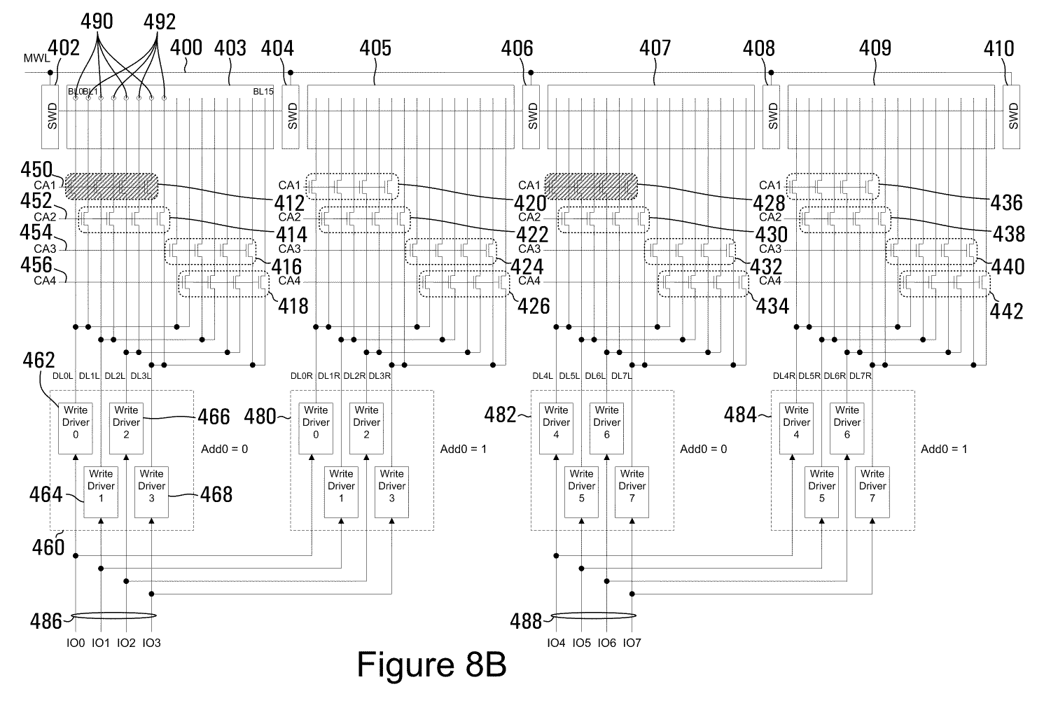

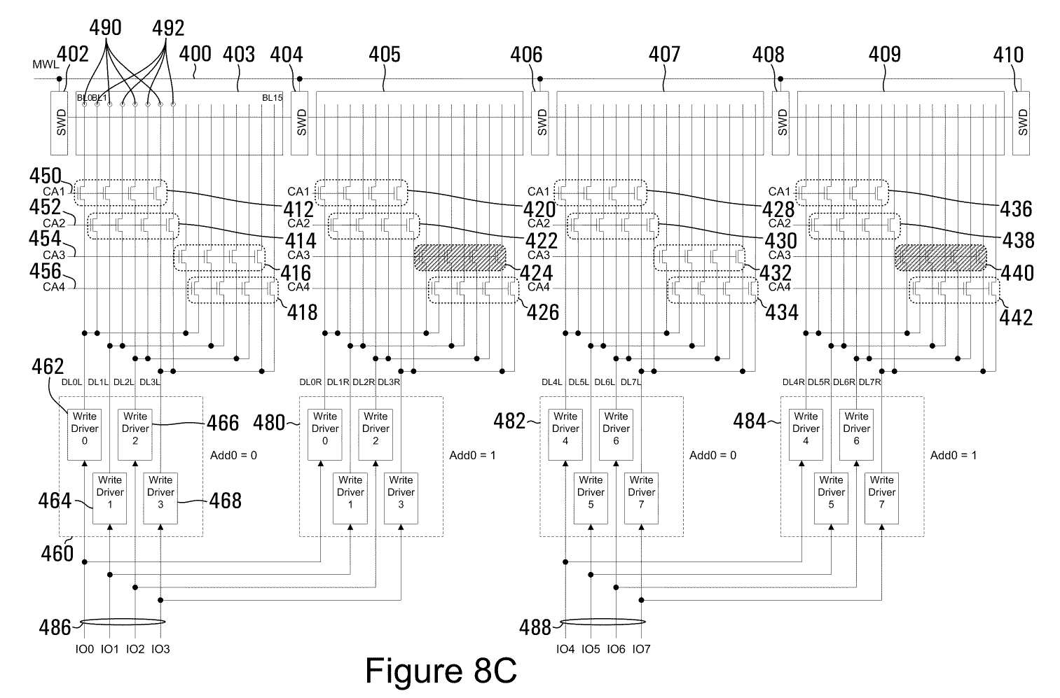

FIG. 8A is a detailed example of a PCM configuration featuring a) partitioned I/O assignment, b) alternate subblock selection and c) alternate bitline selection with adjacent cells which are not programmed to avoid the heat interference from the adjacent cells.

The main wordline for the memory cell array is indicated at 400 and this is connected to sub-wordline drivers 402,404,406,408,410. The main wordline and sub-wordline structure is repeated for each memory cell array (row of cells). The memory cell array contains four PCM block units 403,405,407,409. The first PCM block unit 403 is between sub-wordline drivers 402,404. Bitline select transistor groups 412,414,416,418 are used to select particular cells within the first PCM block unit of an activated main wordline. Bitline select transistor group 412 enables BL0, BL2, BL4 and BL6. Bitline select transistor group 414 enables BL1, BL3, BL5, BL7. The other groups similarly enable respective sets of bitlines. In effect, the bitline select transistor groups cause the cells of the PCM block unit 403 to be arranged into corresponding cell groups which are logical groupings of cells. Each logical grouping of cells includes the PCM cells that are connected to one of the bitline select transistor groups 412,414,416,418. The cell group corresponding to bitline select transistor group 412 contains the first, third, fifth and seventh PCM cells (collectively indicated at 490); the cell group corresponding to bitline select transistor group 414 contains the second, fourth, sixth and eighth PCM cells (collectively indicated at 492); the cell group corresponding to bitline select transistor group 416 contains the ninth, eleventh, thirteenth and fifteenth PCM cells; the cell group corresponding to bitline select transistor group 418 contains the tenth, twelfth, fourteenth and sixteenth PCM cells. The PCM cells for the other PCM block units 405,407,409 are similarly defined such that the PCM block unit 405 between sub-wordline drivers 404,406 contains cell groups associated with bitline select transistor groups 420,422,424,426; the PCM block unit 407 between sub-wordline drivers 406,408 contains cell groups associated with bitline select transistor groups 428,430,432,434; the PCM block unit 409 between sub-wordline drivers 408,410 contains cell groups associated with bitline select transistor groups 436,438,440,442. It can be seen that each cell group does not contain adjacent cells but, rather contains a set of four PCM cells that are spaced apart by one intervening PCM cell that does not form part of the cell group. The transistors of bitline select transistor groups 412,420,428,436 are commonly connected to a first column address signal CA1 450. The transistors of the bitline select transistor groups 414,422,430,438 are commonly connected to a second column address signal CA2 452. The transistors of bitline select transistor groups 416,424,432,440 are commonly connected to a third column address signal CA3 454. The transistors of bitline select transistor groups 418,426,434,442 are commonly connected to a fourth column address signal CA4 456.

The column address decoder 222 generates the column address signals CA1˜CA4. More generally, some embodiments have a selector for selecting between a first set of cells and a second set of cells. The column address decoder 222 is a specific example of such a selector. From the perspective of such a selector, the selector has a first output connected to the first set of cells and has a second output connected to the second set of cells. In some embodiments, such a selector has four outputs for selecting between four sets of cells.

Shown is a set of write drivers 460 for PCM block unit 403. Write driver 0 462 outputs DL0L to the first transistor of each of the four bitline select transistor groups 412,414,416,418. Write driver 1 464 outputs DL1L to the second transistor of each of the four bitline select transistor groups 412,414,416,418. Write driver 2 466 outputs DL2L to the third transistor of each of the four bitline select transistor groups 412,414,416,418 and finally write driver 3 468 outputs DL3L to the fourth transistor of each of the four bitline select transistor groups 412,414,416,418. When CA1 is active, DL0L, DL1L, DL2L, and DL3L are propagated to the cell group associated with bitline select transistor group 412. When CA2 is active, DL0L, DL1L, DL2L, and DL3L are propagated to the cell group associated with bitline select transistor group 414. When CA3 is active, DL0L, DL1L, DL2L, and DL3L are propagated to the cell group associated with bitline select transistor group 416. When CA4 is active, DL0L, DL1L, DL2L, and DL3L are propagated to the cell group associated with bitline select transistor group 418.

In the embodiment described, transistor groups 412, 414 are used to select between cell group 490 and cell group 492. More generally, some embodiments feature a first set of bit lines (e.g. BL0,BL2,BL4,BL6) and a second set of bitlines (e.g. BL1,BL3,BL5,BL7), and each bitline has a switching element for selecting the bitline. Transistor groups 412,414 are specific examples of such switching elements but a person skilled in the art would understand other implementations are possible.

A similar set of write drivers 480,482,484 are shown for each of the second, third and fourth PCM block units 405,407,409 respectively. IOs IO0,IO1,IO2,IO3, collectively indicated at 486 are connected to the write drivers 460 and are also connected to the write drivers 480. However, only write drivers 460 are active when Add0=0, whereas write drivers 480 are active when Add0=1. Similarly, IOs IO4,IO5,IO6,IO7 collectively indicated at 488 are input to write drivers 482 and write drivers 484. Only write drivers 482 are active when Add0=0, whereas write drivers 484 are active when Add0=1.

A similar structure is provided for read sensing, although the details are not included in the Figure.

In some embodiments, each write driver is placed to have short data line connections between two PCM block units including one for the Add0=0 case, ‘L’ postfix and one for the Add0=1 case; ‘R’ postfix. For example, using one more switch between write driver and DL lines, a common write driver for both of 403 and 405 can be employed. So, Add0 is used for switch selection instead of write driver enable. The unselected write drivers do not drive current to the cells. The CA1˜4 signals 450,452,454,456 are used to choose the bitlines according to the address input decoding combination. Only one of the four CA1˜4 signals becomes high and the NMOS transistors that are connected to the high CA signal turn on.

In summary, the wordlines (of which wordline 400 of FIG. 8A is one), the CA1,CA2,CA3,CA4 signals, and the Add0 input work together to control which cells are active.

Wordline: activation of a particular main wordline (e.g. main wordline 400) selects particular row in the memory array. In some embodiments, a wordline is activated by a low on the wordline. Selection of a given wordline correspondingly selects all of the sub wordlines connected to that wordline since they are all commonly connected to the main wordline. A selected sub-wordline is set to ground level through sub-wordline driver (inverter type) to turn on selected diode switches. Deselected sub-wordlines are set to VDD+1V or VDD+2V (α=1V or 2V) level according to operation modes to turn off deselected diode-switches.

CA1,CA2,CA3,CA4: These signals select between the different corresponding subsets the cells within the PCM block units, as detailed above. Depending on these inputs, particular bitlines are selected. Deselected bit-lines (B/L) are set to floating (no voltage or current driving state) to reduce leakage current and parasitic effects at the normal write operation.

Add0—this input controls which set of write drivers are active. A write current (Iwrite) from a write driver flows to a selected bitline (B/L) depending on the data type (IO value=0→set current driving, IO value=1→reset current driving). The write driver current is driven to a cell selected by the sub-wordline low state.

The following table shows the input permutations, and the resulting selected cells:

| CA Selection | Add0 | Selected Cell Groups |
|---|---|---|
| CA1 | 0 | 412, 428 |
| CA2 | 0 | 414, 430 |
| CA3 | 0 | 416, 432 |
| CA4 | 0 | 418, 434 |
| CA1 | 1 | 420, 436 |
| CA2 | 1 | 422, 438 |
| CA3 | 1 | 424, 440 |
| CA4 | 1 | 426, 442 |

It can be seen that for each permutation of inputs, there are 8 selected memory cells. If this same structure is repeated, as in the example of FIG. 6, on the other side of the address decoder, then each permutation of inputs selects a total of 16 memory cells.

By way of example, FIG. 8B shows the selected cells shaded for the case where CA1 is selected and Add0=0. FIG. 8C shows the selected cells shaded for the case where CA3 is selected and Add=1.

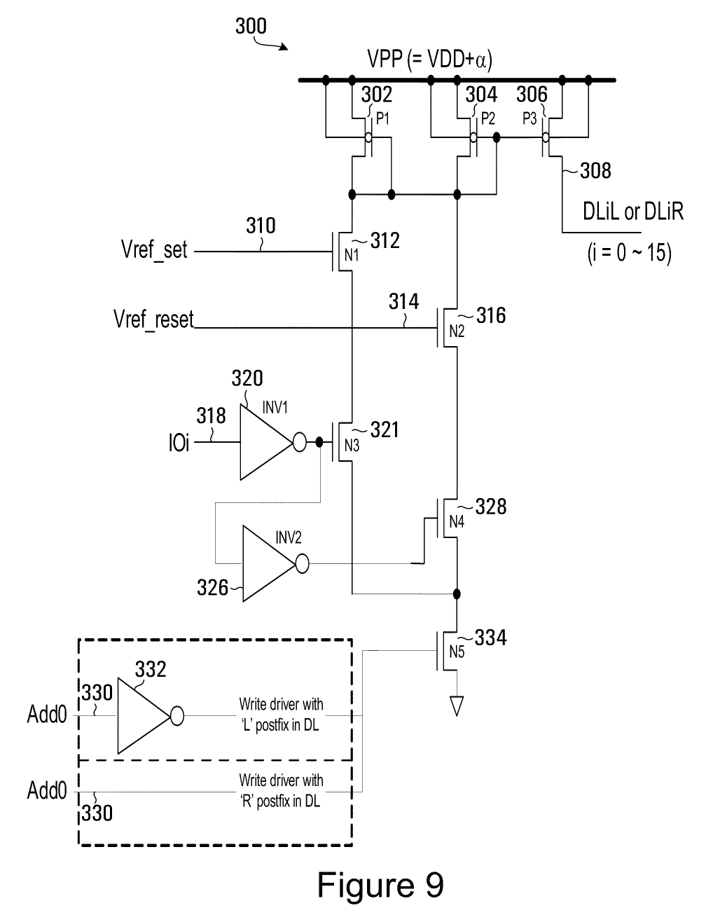

FIG. 9 shows a detailed example of a write driver with address control. A data bit is input at IOi 318. This is inverted in inverter INV1 320 the output of which is connected to the gate of transistor N3 321. The output of INV1 320 is also input to inverter INV2 326 the output of which is connected to the gate of transistor N4 328. A voltage reference Vref_set is input at 310 to the gate of transistor N1 312. A voltage reference for the reset operation is input, Vref_reset 314 is input to the gate of transistor N2 316. Shown is a current mirror structure 300 that includes transistor P1 302,P2 304 and P3 306. It is noted that all the terminals of P1 302 and P2 304 are commonly connected and could alternatively be merged into a single PMOS transistor The gates of transistors P1 302 and P2 304 are connected to the gate of transistor P3 306 which produces the output current 308. For odd numbered blocks, the output is DLiL, while for even numbered blocks the output is DLiR, where i equals 0 to 15. Whether or not an even numbered block or an odd numbered block is selected is controlled through address input 330. In write drivers for odd numbered blocks, the address input Add0 330 is connected through an inverter 332 to the gate of transistor N5 334. On the other hand, in even numbered block units, the address input Add0 330 is connected directly to the gate of transistor N5 334. For a given write driver that is connected to a bitline that is to be deselected, Add0 330 makes the connected NMOS N5 334 turn off (in the illustrated embodiment, either by being high for odd numbered block units, or low for even numbered block units). As a result, there is no current driving due to the off states of P1 302, P2 304, and P3 306, and DLiL/DLiR is made to have a floating state (No current driving state). For a given write driver that is connected to a bitline that is to be selected, Add0 330 makes the connected NMOS N5 334 turn on. Once P1 302 and P2 304 turn on due to a set or reset, the write driver invokes a current through P3 306 to DLiL or DLiR 308. The current amount is determined by which data is asserted. Through the logic of inverters INV1 320, INV2 326, and transistors N3 321, N4 328, an amorphizing current is invoked P3 306 to DLiL or DLiR 308 IOi is high (logical ‘1’), whereas, a crystaliizing current is invoked P3 306 to DLiL or DLiR 308 when IOi is low (logical ‘0’).

Specifically, if IOi 318 is low (Logical ‘0’), NMOS N3 321 is turned on and Vref_set connected NMOS N1 312 is turned on by the on state of N3 321. By this, the drain and gate of P1 302 and P2 304 go to a low state and due to the current mirror structure, a current which is the same as the sum of the currents coming out of P1 and P2 is invoked in PMOS P3 306 so as to produce DLiL or DLiR 308. In case of high (Logical ‘1’) in IOi, NMOS N4 328 is turned on, Vref_reset connected NMOS N2 316 is turned on by the state of N4 328. In this case, again the drain and gate of P1 302 and P2 304 go to a low state, and due to the current mirror structure, a current which is the same as the sum of the currents coming out of P1 and P2 is invoked in the P3 PMOS transistor 306 so as to produce DLiL or DLiR 308. Transistors N3 321 and N4 328 have difference sizes such that the current invoked for the logical ‘1’ case is different than for the logical ‘0’ case. In a specific example, the set current is about 0.2 mA, whereas the reset current is about 1 mA, but it should be clearly understood that different values can be used depending upon cell implementation. Using the Add0 signal, odd numbered blocks or even numbered blocks can be selected. A different pulse duration is produced for the low state as opposed to the high state of IOi. This can be controlled either by controlling pulse widths of Vref_set and Vref_reset such that the pulse width for Vref_reset is longer than that for Vref_set. Alternatively, different pulse widths can be used for IOi for the logical ‘1’ as opposed to logical ‘0’.

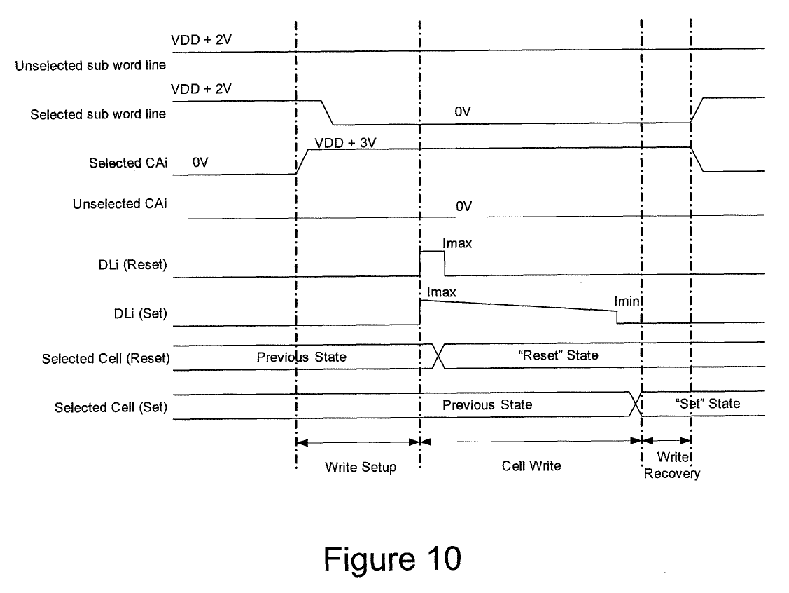

FIG. 10 is a detailed timing diagram showing timing of signals for writing to a cell.

The above-described embodiments include the three features of a) partitioned IO, b) alternating sub-block selection, and c) alternating bit-lines. More generally, in some embodiments, a PCM configuration is provided that includes one, or two of these features.

In the embodiments described above, the device elements and circuits are connected to each other as shown in the figures, for the sake of simplicity. In practical applications of the present invention, elements, circuits, etc. may be connected directly to each other. As well, elements, circuits etc. may be connected indirectly to each other through other elements, circuits, etc., necessary for operation of devices and apparatus. Thus, in actual configuration, the circuit elements and circuits are directly or indirectly coupled with or connected to each other.

The above-described embodiments of the present invention are intended to be examples only. Alterations, modifications and variations may be effected to the particular embodiments by those of skill in the art without departing from the scope of the invention, which is defined solely by the claims appended hereto.

What is claimed is:

1. An apparatus comprising:
a plurality of adjacent phase change memory (PCM) cells;
wherein a memory location for accessing includes a subset of the PCM cells, such that each PCM cell of the subset is non-adjacent to each other PCM cell of the subset.

2. The apparatus of claim 1 wherein:
the plurality of adjacent PCM cells is divided into a first set of odd numbered PCM cells and a second set of even numbered PCM cells, such that the cells of the first and second set alternate between belonging to the first set and belonging to the second set;
the apparatus further comprising a selector for selecting the first set of cells or the second set of cells.

3. The apparatus of claim 2 wherein:
when the selector selects the first set of cells, a memory location for reading or writing comprises the first set of cells and not the second set of cells;
when the selector selects the second set of cells, a memory location for reading or writing comprises the second set of cells and not the first set of cells.

4. The apparatus of claim 2 wherein the selector comprises:
a first output connected to the first set of cells;
a second output connected to the second set of cells.

5. The apparatus of claim 2 wherein:
the plurality of adjacent PCM cells further comprise a third set of odd numbered PCM cells and a fourth set of even numbered set of PCM cells, such that the cells of the third and fourth sets alternate between belonging to the third set and belonging to the fourth set;
wherein the selector comprises:
a first output connected to the first set of cells;
a second output connected to the second set of cells;
a third output connected to the third set of cells; and
a fourth output connected to the fourth set of cells.

6. The apparatus of claim 2 further comprising:
a first set of bit lines and a second set of bitlines, each bitline comprising a switching element for selecting the bitline;
wherein the switching elements of the first set of bitlines are connected to the first output and the switching element of the second set of bitlines are connected to the second output.

7. An apparatus comprising:
a first memory cell array comprising a first plurality of PCM block units, each PCM block unit containing a plurality of memory cells, the first plurality of PCM block units divided into a first block set and a second block set such that each PCM block unit belonging to the first block set is non-adjacent to any other PCM block unit of the first block set, and each PCM block unit belonging to the second block set is non-adjacent to any other PCM block unit of the second block set;
a first selector configured to select between the first block set and the second block set; and
a wordline driver structure comprising:
a first plurality of sub-wordline drivers; and
a first main wordline driver that drives the first plurality of PCM block units via the first plurality of sub-wordline drivers,
wherein when the first selector selects the first block set, a memory location for accessing comprises memory cells of each block of the first block set, and when the first selector selects the second block set, a memory location for accessing comprises memory cells of each block of the second memory set.

8. The apparatus of claim 7 wherein each PCM block unit comprises:
a plurality of adjacent PCM (phase change memory) cells;
wherein for a PCM block unit selected by the first selector, the memory location for accessing includes a subset of the PCM cells of the PCM block unit, such that each PCM cell of the subset is non-adjacent to each other PCM cell of the subset.

9. The apparatus of claim 8 wherein each PCM block unit comprises a plurality of adjacent memory cells divided into a first set of odd numbered memory cells and a second set of even numbered set of memory cells, such that the cells of the first and second set alternate between belonging to the first set and belonging to the second set;
the apparatus further comprising a second selector that selects between the first sets of cells and the second sets of cells.

10. The apparatus of claim 9 wherein:
when the first selector selects the first block set and the second selector selects the first set of cells, a memory location for reading or writing comprises memory cells of the first set of cells of each block of the first block set;
when the first selector selects the first block set and the second selector selects the second set of cells, a memory location for reading or writing comprises memory cells of the second set of cells of each block of the first block set;
when the first selector selects the second block set and the second selector selects the first set of cells, a memory location for reading or writing comprises memory cells of the first set of cells of each block of the second block set;
when the first selector selects the second block set and the second selector selects the second set of cells, a memory location for reading or writing comprises memory cells of the second set of cells of each block of the second block set.

11. The apparatus of claim 9 wherein:
for each PCM block, the plurality of adjacent PCM cells further comprise a third set of odd numbered PCM cells and a fourth set of even numbered set of PCM cells, such that the cells of the third and fourth sets alternate between belonging to the third set and belonging to the fourth set;
wherein the second selector comprises:
a first output connected to the first set of cells;
a second output connected to the second set of cells;
a third output connected to the third set of cells; and
a fourth output connected to the fourth set of cells.

12. The apparatus of claim 7 further comprising:
a second memory cell array comprising a second plurality of PCM block units, the second plurality of PCM block units divided into a third block set and a fourth block set such that each PCM block unit belonging to the third set is non-adjacent to any other PCM block unit of the third set, and each PCM block unit belonging to the fourth set is non-adjacent to any other PCM block unit of the fourth set;
the wordline driver structure further comprises a second main wordline driver that drives the second plurality of PCM block units via a second plurality of sub-wordline drivers;
the first selector selects one of:
a) both the first block set and the third block set;
b) both the second block set and the fourth block set;
wherein when the selector selects the first block set and the third block set, a memory location for accessing comprises memory cells of each block of the first block set and memory cells of each block of the third block set;
wherein when the selector selects the second block set and the fourth block set, the memory location for accessing comprises memory cells of each block of the second block set and memory cells of each block of the fourth block set.

13. The apparatus of claim 12 comprising:
an address decoder;
wherein the first main wordline driver and the second main wordline driver are commonly activated by the address decoder.

14. The apparatus of claim 12 wherein:
each PCM block unit comprises a plurality of adjacent PCM (phase change memory) cells;
wherein for a PCM block unit selected by the first selector, the memory location for accessing includes a subset of the PCM cells of the PCM block unit, such that each PCM cell of the subset is non-adjacent to each other PCM cell of the subset.

15. The apparatus of claim 14 wherein:
each PCM block unit comprises a plurality of adjacent memory cells divided into a first set of odd numbered memory cells and a second set of even numbered set of memory cells, such that the cells of the first and second set alternate between belonging to the first set and belonging to the second set;
a second selector that selects between the first sets of cells and the second sets of cells.

16. The apparatus of claim 14 wherein:
when the first selector selects the first block set and the second selector selects the first set of cells, a memory location for reading or writing comprises memory cells of the first set of cells of each block of the first block set;
when the first selector selects the first block set and the second selector selects the second set of cells, a memory location for reading or writing comprises memory cells of the second set of cells of each block of the first block set;
when the first selector selects the second block set and the second selector selects the first set of cells, a memory location for reading or writing comprises memory cells of the first set of cells of each block of the second block set;
when the first selector selects the second block set and the second selector selects the second set of cells, a memory location for reading or writing comprises memory cells of the second set of cells of each block of the second block set.

17. The apparatus of claim 16 wherein:
for each PCM block, the plurality of adjacent PCM cells further comprise a third set of odd numbered PCM cells and a fourth set of even numbered PCM cells, such that the cells of the third and fourth sets alternate between belonging to the third set and belonging to the fourth set;
wherein the selector comprises a first output connected to select the first set of cells, a second output connected to select the second set of cells, a third output connected to select the third set of cells, and a fourth output connected to select the fourth set of cells.

18. A memory device comprising:
a memory cell array comprising a first PCM array and a second PCM array, the first PCM array comprising a first plurality of PCM block units, the second PCM array comprising a second plurality of PCM block units;
a wordline driver structure comprising, for each of a plurality of wordlines:
a first main wordline driver configured to drive the first PCM array via a first plurality of sub-word drivers configured to drive the first plurality of PCM block units;
a second main wordline driver configured to drive the second PCM array via a second plurality of sub-word drivers configured to drive the second plurality of PCM block units;
an address decoder configured to commonly activate the first main wordline driver and the second main wordline driver;
wherein a memory location for accessing comprises selected memory cells of the first memory cell array and selected memory cells of the second memory cell array.

19. The memory device of claim 18 wherein the memory location for reading or writing comprises selected memory cells of the first memory cell array and selected memory cells of the second memory cell array.

20. A method comprising:
accessing phase change memory cells such that a memory location for accessing includes a subset of the PCM cells, such that each PCM cell of the subset is non-adjacent to each other PCM cell of the subset.

21. The method of claim 20 wherein:
the plurality of adjacent PCM cells is divided into a first set of odd numbered PCM cells and a second set of even numbered PCM cells, such that the cells of the first and second set alternate between belonging to the first set and belonging to the second set;
the method further comprising selecting the first set of cells or the second set of cells.

22. The method of claim 21 wherein:
when the selector selects the first set of cells, a memory location for reading or writing comprises the first set of cells and not the second set of cells;
when the selector selects the second set of cells, a memory location for reading or writing comprises the second set of cells and not the first set of cells.

23. The method of claim 21 wherein:
the plurality of adjacent PCM cells further comprise a third set of odd numbered PCM cells and a fourth set of even numbered set of PCM cells, such that the cells of the third and fourth sets alternate between belonging to the third set and belonging to the fourth set;
the method further comprising selecting between the first set of cells, the second set of cells, the third set of cells and the fourth set of cells.

24. A method comprising:
for a first memory cell array comprising a first plurality of PCM block units, each PCM block unit containing a plurality of memory cells, the first plurality of PCM block units divided into a first block set and a second block set such that each PCM block unit belonging to the first block set is non-adjacent to any other PCM block unit of the first block set, and each PCM block unit belonging to the second block set is non-adjacent to any other PCM block unit of the second block set, selecting between the first block set and the second block set;
using a first main wordline driver to drive the first plurality of PCM block units via a first plurality of sub-wordline drivers,
wherein when the first block set is selected, accessing a memory location that comprises memory cells of each block of the first block set, and when the second block set is selected, accessing a memory location for accessing that comprises memory cells of each block of the second memory set.

25. The method of claim 24 wherein each PCM block unit comprises:
a plurality of adjacent PCM (phase change memory) cells;
wherein for a PCM block unit that is selected, the memory location for accessing includes a subset of the PCM cells of the PCM block unit, such that each PCM cell of the subset is non-adjacent to each other PCM cell of the subset.

26. The method of claim 24 wherein each PCM block unit comprises a plurality of adjacent memory cells divided into a first set of odd numbered memory cells and a second set of even numbered set of memory cells, such that the cells of the first and second set alternate between belonging to the first set and belonging to the second set;
the method further comprising selecting between the first sets of cells and the second sets of cells.

27. The method of claim 26 wherein:
when the first block set and the first set of cells are selected, a memory location for reading or writing comprises memory cells of the first set of cells of each block of the first block set;
when the first block set and the second set of cells are selected, a memory location for reading or writing comprises memory cells of the second set of cells of each block of the first block set;
when the second block set and the first set of cells are selected, a memory location for reading or writing comprises memory cells of the first set of cells of each block of the second block set;
when the second block set and the second set of cells are selected, a memory location for reading or writing comprises memory cells of the second set of cells of each block of the second block set.

28. The method of claim 24 further comprising:
for a second memory cell array comprising a second plurality of PCM block units, the second plurality of PCM block units divided into a third block set and a fourth block set such that each PCM block unit belonging to the third set is non-adjacent to any other PCM block unit of the third set, and each PCM block unit belonging to the fourth set is non-adjacent to any other PCM block unit of the fourth set, using a second main wordline driver to drive the second plurality of PCM block units via a second plurality of sub-wordline drivers;
selecting comprises selecting one of:
a) both the first block set and the third block set;
b) both the second block set and the fourth block set;
wherein when the first block set and the third block set are selected, a memory location for accessing comprises memory cells of each block of the first block set and memory cells of each block of the third block set;
wherein when the second block set and the fourth block set are selected, the memory location for accessing comprises memory cells of each block of the second block set and memory cells of each block of the fourth block set.

29. The method of claim 28 further comprising:
commonly activating the first main wordline driver and the second main wordline driver (204).
